(19) United States
(12) Patent Application Publication
(10) Pub. No.: US 2010/0155884 A1
(43) Pub. Date: Jun. 24, 2010

(54) MELTING FUSE OF SEMICONDUCTOR AND METHOD FOR FORMING THE SAME

(75) Inventor: Hyung Jin PARK, Icheon-si (KR)

Correspondence Address: AMPACC Law Group, 3500 188th Street S.W., Suite 103, Lynnwood, WA, 98037, US

(73) Assignee: Hynix Semiconductor Inc., Icheon-si (KR)

(21) Appl. No.: 12/495,726

(22) Filed: Jun. 30, 2009

(30) Foreign Application Priority Data
Dec. 24, 2008 (KR) 10-2008-0133216

(51) Int. Cl. H01L 23/525; H01L 21/768

(52) U.S. Cl. 257/529; 438/132; 257/209; 257/741; 438/601; 257/E23.149; 257/E21.592

(57) ABSTRACT

The present invention discloses a fuse of a semiconductor device and manufacturing method thereof. The fuse of a semiconductor device of the present invention includes a first conductive pattern; and a second conductive pattern which is separated from the first conductive pattern with a given gap, wherein the first conductive pattern and the second conductive pattern are melted in a laser irradiation to be connected. Accordingly, the present invention prevents the damage of the adjacent fuse in the repair process, enabling to improve the reliability of device and accomplish the high integration.

### CROSS-REFERENCE TO RELATED APPLICATION

The priority of Korean patent application No. 10-2008-0133216 filed on Dec. 24, 2008, the disclosure of which is hereby incorporated in its entirety by reference, is claimed.

### BACKGROUND OF THE INVENTION

The present invention relates to a method of manufacturing a semiconductor device, more particularly, to a method of manufacturing a fuse of a semiconductor device for improving the repair yield.

If any one of numerous cells in a semiconductor memory device fails, the device may not be able to properly perform the function as a memory, and thus it is treated as defective goods. However, it is not efficient in terms of yield to discard the semiconductor memory device as defective goods even though a fail was generated in a part of the cells in the semiconductor memory device.

Therefore, recently, redundancy cells are being placed in the semiconductor memory device. When a bad cell is generated, the bad cell is replaced with a redundancy cell. That is, the redundancy cell is provided in the semiconductor memory device in advance, so that the semiconductor memory device would not have to be discarded for a few defective cells. The process of replacing the bad cell with a redundancy cell is called a repair process.

In order to perform the repair process, the semiconductor memory device includes a fuse unit which stores address information of the bad cell according to the connection state of fuse.

FIG. 1a is a plan view illustrating a conventional fuse unit of a semiconductor device, and FIG. 1b is a cross-sectional view taken along Y-Y′ of FIG. 1a.

As shown in FIGS. 1a and 1b, a plurality of fuses 101 are formed on a substrate 100 in which a certain substructure is equipped. At this time, the fuse 101 can be formed together with a plate electrode or metal line of a capacitor.

An insulating layer 102 covering the fuse 101 is formed in the upper portion of the fuse 101, and the insulating layer 102 includes a fuse box 103. At this time, a certain thickness T of the insulating layer 102 remains in the upper portion of the fuse 101 of the fuse box 103.

Conventionally, after forming the above described fuse unit, a repair was performed by using a fuse blowing method of cutting a corresponding fuse 101 by irradiating a laser to a selected fuse 101 through the fuse box 103. However, the fuse blowing method has a following problem.

Firstly, the thickness T of the insulating layer 102 which remains in the upper portion of the fuse 101 has to be uniform so as to reliably perform the fuse cutting. However, in the entire substrate 100, it is very difficult to uniformly form the thickness T of the insulating layer 102 remaining in the upper portion of the fuse 101. Thus, in some cases, the fuse cutting is not normally generated. Accordingly, there is a problem where the repair yield is reduced.

Moreover, the adjacent fuse 101 may be damaged by the explosion power generated in the fuse cutting. Moreover, a conductive by-product may be generated by the explosion power generated in the fuse cutting and the adjacent fuse 101 may be damaged due to the generated conductive by-product, or an electrical short is generated between the adjacent fuses 101.

Moreover, due to the problem resulting from the above-described explosion power and the conductive by-product, the length L of the fuse 101 and the gap W between the adjacent fuses 101 need to be increased to secure a process margin. Hence, there is a problem in that the integration density of semiconductor devices including the fuse unit is lowered.

### BRIEF SUMMARY OF THE INVENTION

Various embodiments of the invention are directed to perform a repair without cutting the fuse by improving the structure of a fuse unit such that the repair can be performed with a more simple logic and a problem resulted from the fuse cutting can be solved.

According to an embodiment of the present invention, a fuse of a semiconductor device comprises: a first conductive pattern; and a second conductive pattern which is separated from the first conductive pattern with a given gap, wherein the first conductive pattern and the second conductive pattern are melted in a laser irradiation to be connected.

Preferably, the first conductive pattern and the second conductive pattern are formed in the same plane.

Preferably, a fuse of a semiconductor device further comprises an insulating layer which is formed on an upper portion of the first conductive pattern and the second conductive pattern and an upper portion of a space where the first conductive pattern and the second conductive pattern are separated.

Preferably, the given gap is smaller than ⅓ to 1/2.5 of the height of the first conductive pattern and the second conductive pattern.

Preferably, the end portion of the first conductive pattern is formed with a convexly protruded form, and the end portion of the second conductive pattern is formed with a concave form receiving the end portion of the first conductive pattern.

Preferably, the end portion of the first conductive pattern and the end portion of the second conductive pattern are symmetrically formed each other with [symbol] shaped feature.

Preferably, the first conductive pattern and the second conductive pattern are formed with one of the tungsten W, the aluminium Al, the titanium Ti, the copper Cu, the titanium nitride TiN, the Iridium Oxide IrO2, the tungsten silicide WSi and the titanium silicide TiSi.

According to an embodiment of the present invention, a method of manufacturing a fuse of a semiconductor device comprises: forming a plurality of fuses on a substrate including a substructure; and forming an insulating layer in an upper portion of the fuse, wherein, in forming a plurality of fuses, each fuse is formed with a first conductive pattern and a second conductive pattern which are separated with a given gap.

Preferably, in forming an insulating layer, a void is formed in a lower portion of a space in which the first conductive pattern and the second conductive pattern are separated.

Preferably, the first conductive pattern and the second conductive pattern are formed to be separated with a gap which is smaller than ⅓ to 1/2.5 of the height of the pattern.

The present invention prevents the damage of the adjacent fuse in the repair process by forming the fuse in such a manner that the repair process is made by a melting method not by a blowing method, thereby, enabling to improve the reliability of device and accomplish the high integration.

### BRIEF DESCRIPTION OF THE DRAWINGS

FIG. 1a is a plan view illustrating a conventional fuse unit of a semiconductor device,

FIG. 1b is a cross-sectional view taken along Y-Y′ of FIG. 1a.

FIG. 2 is a plan view illustrating a structure of fuse according to a first preferred embodiment of the present invention.

FIG. 3a is a cross-sectional diagram taken along A-A′ of FIG. 2.

FIG. 3b is a cross-sectional diagram taken along B-B′ of FIG. 2.

FIG. 4 is a diagram illustrating a fuse contact unit according to the present invention, which is melted to be connected.

FIG. 5 is a plan view illustrating a structure of fuse according to a second preferred embodiment of the present invention.

FIGS. 6a to 6c are process cross-sectional diagrams illustrating a method of manufacturing a fuse having the structure of FIG. 3.

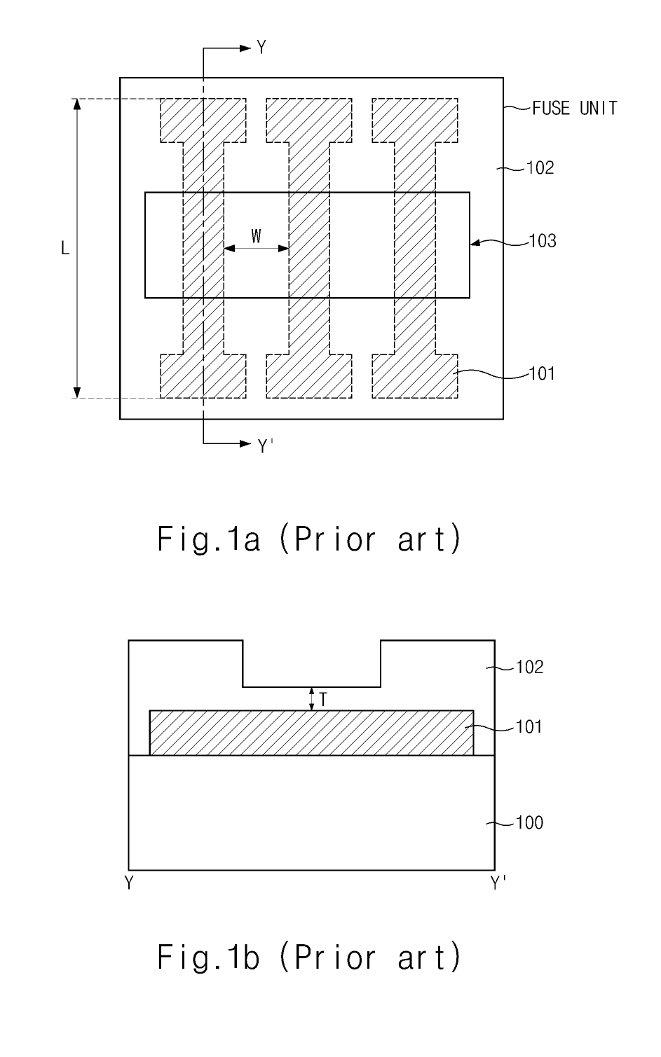

### DESCRIPTION OF EMBODIMENTS

Embodiments of the present invention are described in detail with reference to the accompanying drawings. The same reference numbers are used throughout the drawings to refer to the same or like parts.

Firstly, the technical principle of the present invention is briefly illustrated.

In the present invention, the initial state of each fuse is separated into a conductive pattern of two parts. Thereafter, the fuse of a fuse contact unit is melted by irradiating a laser onto the separated part (hereinafter, ‘fuse contact unit’) so that the separated conductive pattern is electrically connected. That is, in the present invention, the repair process is performed by using a fuse melting method not by a fuse blowing method. At this time, in the present invention, two conductive patterns can be simultaneously formed with one patterning process by forming the separated two fuses on the same plane.

Moreover, in the present invention, an overhang of an insulating layer is used in order to secure a space (i.e., void) in which the melted fuse can be connected while the conductive pattern is not exposed to an external environment. The overhang of an insulating layer is caused in the formation of the insulating layer in the upper portion of a fuse so that a void is formed in the lower portion of fuse contact unit.

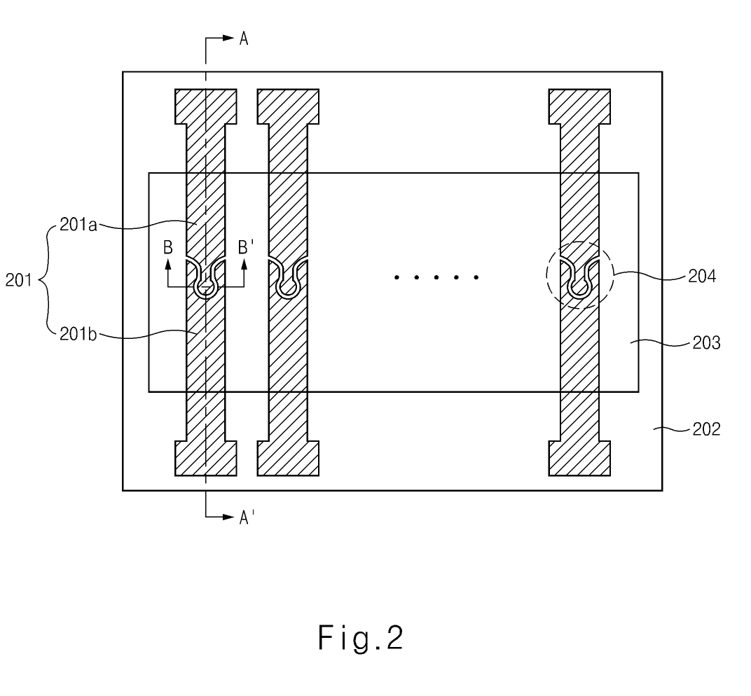

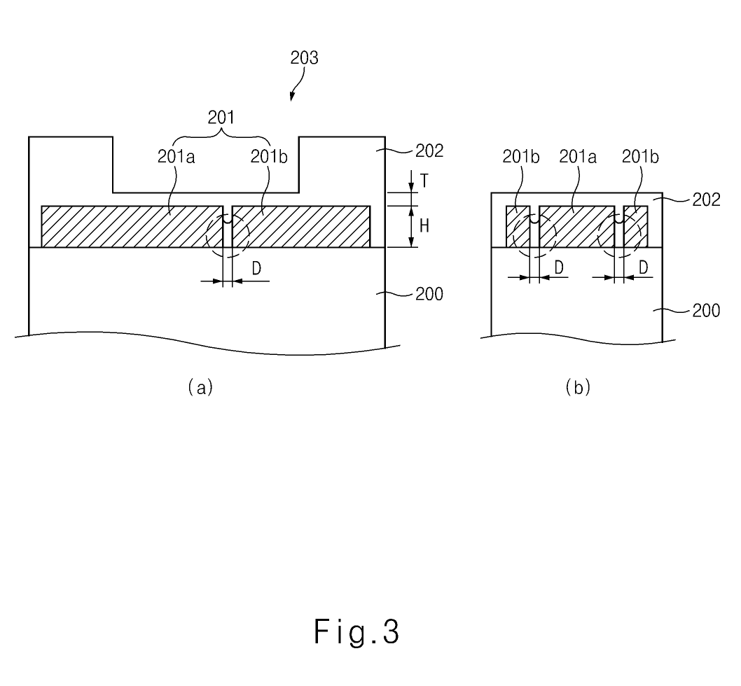

FIG. 2 is a plan view illustrating a structure of fuse according to a first embodiment of the present invention. FIG. 3a is a cross-sectional diagram taken along A-A′ of FIG. 2. FIG. 3b is a cross-sectional diagram taken along B-B′ of FIG. 2.

A plurality of line fuses 201 are formed on a substrate 200 in which a certain substructure is equipped.

An insulating layer 202 covering a fuse 201 is formed in the upper portion of the fuse 201. At this time, in the fuse box 203 region to which a laser is irradiated, the insulating layer 202 is formed with a given thickness T in such a manner that the energy of an irradiated laser can be sufficiently delivered to the fuse 201. The height H of a fuse is formed to be 8000 or more.

Particularly, each fuse 201 of the present invention includes a fuse contact unit 204 which electrically separates the fuse 201 of line-shape into two parts 201a, 201b in the fuse box 203. The fuse contact unit 204 is a region to which laser is irradiated in the repair process, and electrically connects the fuse 201 when the fuse contact unit 204 is melted by the laser.

That is, in an initial state, (i.e., before a repair process is performed), each fuse 201 of the present invention is not connected as one continuous line, but formed in such a manner that two conductive patterns 201a, 201b are electrically separated with a constant gap D. If a laser is irradiated to the fuse contact unit 204 in the repair process, the first conductive pattern 201a and the second conductive pattern 201b are melted and electrically connected.

At this time, in the fuse contact unit 204, the gap D between the first conductive pattern 201a and the second conductive pattern 201b are formed in the upper portion of the fuse 201 in such a manner that an inter metal dielectric (IMD) does not gap fill the space between the first conductive pattern 201a and the second conductive pattern 201b and a void (refer to dotted circles in FIG. 3) is formed to be approximately 50% of the height of the fuse 201 (4000 Å˜5000 Å).

Generally, if the fuse 201 is formed in such a manner that the aspect ratio D:H of the gap D between the first conductive pattern 201a and the second conductive pattern 201b to the fuse height H becomes 1:2.5˜1:3 or more, an overhang phenomenon is generated during the formation of the insulating layer 202. The overhang is generated in the upper portion of the fuse 201 such that the insulator is not gap filled in the lower portion of the fuse contact unit 204 and a void is generated in the lower portion.

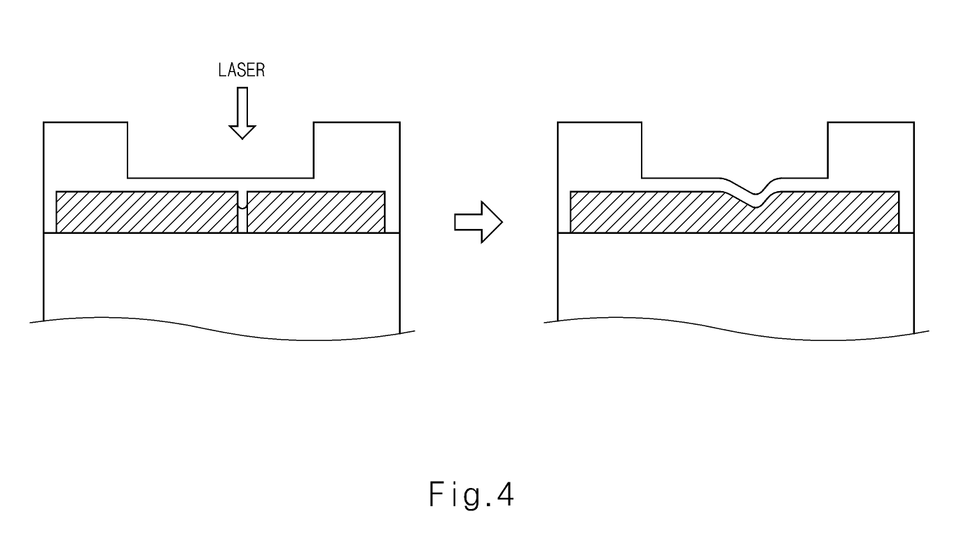

In the present invention, in the formation of the insulating layer 202 on the upper portion of the fuse 201, a void is intentionally formed in the lower portion of the fuse contact unit 204. The first conductive pattern 201a and the second conductive pattern 201b are then connected to each other by a laser in a repair process. The laser is irradiated locally at the fuse contact unit 204 such that the conductive patterns 201a and 201b are melted and flow into the void (see FIG. 4). This is done while maintaining the integrity of the insulating layer 202, which prevents the fuse 201 from being exposed to the external environment.

As described above, the present invention does not use the fuse blowing method but uses a fuse melting method such that the explosion phenomenon, for example, the explosion in the fuse cutting is not generated, thereby, does not affect the adjacent fuses. Moreover, the present invention can prevent damage to the insulating layer due to the explosion phenomenon so that the fuse is not exposed to the external environment, thereby, the reliability of fuse can be increased.

Moreover, the present invention can form the fuse with one conventional patterning process by forming two conductive patterns 201a, 201b. The exposed surface area (i.e., in the void) where the first conductive pattern 201a and the second conductive pattern 201b face each other in the fuse contact unit 204 may be formed as large as possible so that two conductive patterns 201a, 201b can be more reliably connected during the fuse melting.

Therefore, in the present invention, when separating the fuse 201 into the first conductive pattern 201a and the second conductive pattern 201b, the minor axis of the fuse 201 is not separated in a straight line but is separated in a zig zag or other pattern to increase the length of the break line.

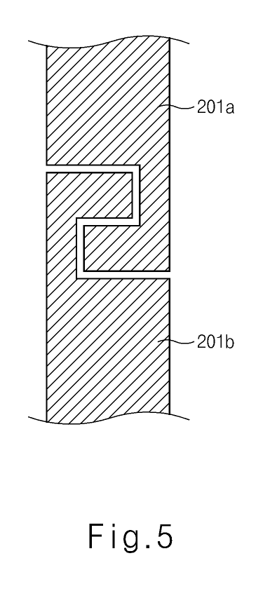

For example, as shown in FIG. 2, the end portion of the first conductive pattern 201a is convexly protruded with a scoop shape while the end portion of the second conductive pattern 201b adjacent to it is formed with a concave shape which receives the end portion of the first conductive pattern 201a. Another example, as shown in FIG. 5, the end portion of the first conductive pattern 201a and the end portion of the second conductive pattern 201b can be formed to be symmetrical with an [symbol] shaped feature.

The shape of FIGS. 2 and 5 are just two embodiments of the present invention and various modifications are possible.

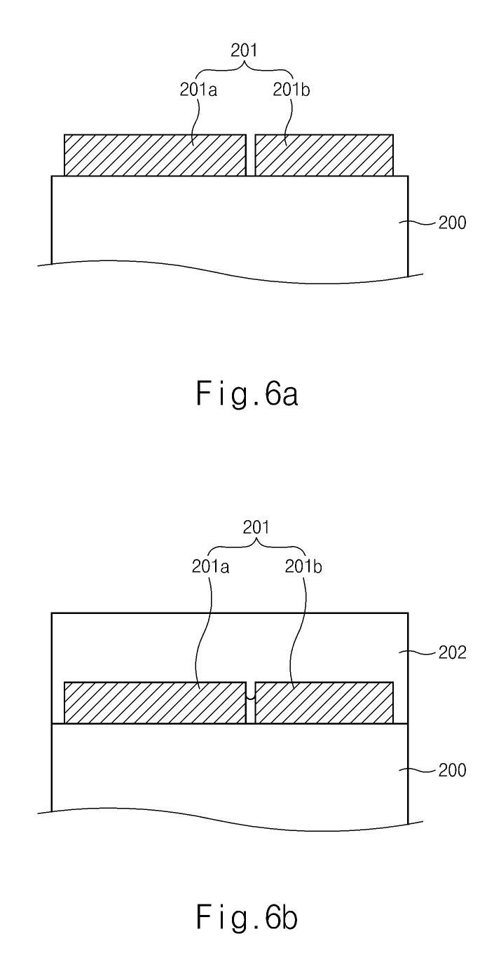

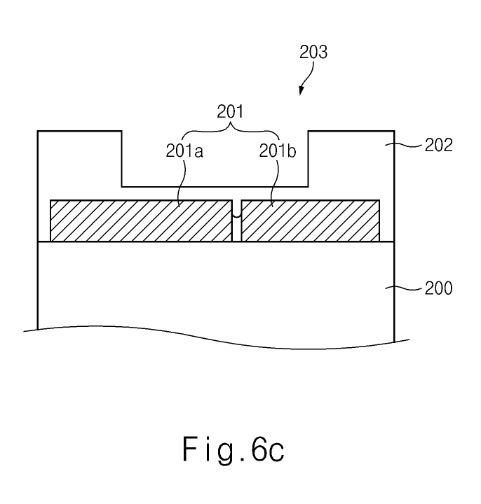

FIGS. 6a to 6c are cross-sectional diagrams illustrating a method of manufacturing a fuse having the structure of FIG. 3.

Referring to FIG. 6a, a plurality of fuses 201 (in FIG. 5, only one fuse is shown) are patterned in the upper portion of the fuse region of the substrate 200 in which a certain substructure (not shown) has already been formed.

At this time, the two fuse regions 201a, 201b are separated with a constant gap D as shown in FIG. 2 or FIG. 5 to form one fuse 201. That is, in the present invention, each fuse 201 is formed with an initial state which is electrically separated. At this time, the aspect ratio D:H of the gap D between the first conductive pattern 201a and the second conductive pattern 201b to the height H of the fuse 201 is set to be 1:2.5˜1:3 or more.

The fuse 201 can be formed with one of a metal layer, a conductive metal nitride layer, a conductive metal oxide layer, a metal silicide layer or a stacked combination of those materials. For example, tungsten W, aluminium Al, titanium Ti, copper Cu and so on can be used as a metal layer. The titanium nitride TiN layer can be used as a conductive metal nitride layer. The Iridium Oxide IrO2 layer can be used as a conductive metal oxide layer. The tungsten silicide WSi, the titanium silicide TiSi can be used as a metal silicide layer. Moreover, such a fuse pattern 201 is not formed not by additionally depositing the metal material layer but can be patterned together when the plate electrode or metal line of a capacitor is formed.

Referring to FIG. 6b, an insulating layer 202 is formed on the upper portion of the substrate 200 and fuse 201. The insulating layer 202 can be formed with an oxide layer. Silicon oxide film (SiO2), Boron Phosphorus Silicate Glass (BPSG), Phosphorus Silicate Glass (PSG), Tetra Ethyle Ortho Silicate (TEOS), Un-doped Silicate Glass (USG), Spin On Glass (SOG), High Density Plasma (HDP), Spin On Dielectric (SOD) and so on can be used as an oxide layer.

As described, in the formation of the insulating layer 202 in the upper portion of the fuse 201, the aspect ratio D:H of the gap D between the first conductive pattern 201a and the second conductive pattern 201b to the height H of the fuse 201 may be made 1:2.5˜1:3 or more. This generates an overhang of the insulating layer in the upper portion of the separated space due to the step coverage of the insulating layer such that the insulating layer does not gap fill the lower portion but creates a void.

That is, in the present invention, the separated space between the first conductive pattern 201a and the second conductive pattern 201b is not gap filled by the insulating layer 202, so that the void is intentionally formed. Accordingly, it is advantageous for the void formation to form the fuse 201 with the thickness of the metal line as large as possible when forming the fuse 201 with the metal line.

Referring to FIG. 6c, the insulating layer of the fuse box 203 region to which a laser is irradiated is etched to a certain depth, so that only an insulating layer of a given thickness above the fuse 201 remains in the fuse box 203 region. This allows the heat energy of the irradiated laser to be sufficiently delivered to the fuse 201.

In the above-described embodiment, it was explained that the insulating layer 202 is formed in the upper portion of the fuse 201 so that the fuse 201 is not exposed to the external environment in the fuse contact unit 204. However, the fuse 201 can also be formed without the insulating layer 202.

In that case, the fuse 201 is exposed to the external environment, but the process margin for the height H of the fuse 201 and the gap D between the first conductive pattern 201a and the second conductive pattern 201b can be better secured in the formation of the fuse 201.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory DRAM device or non volatile memory device. Other additions, subtractions, or modifications are obvious in view of the present disclosure and are intended to fall within the scope of the appended claims.

What is claimed is:

1. A fuse of a semiconductor device, comprising:
a first conductive pattern; and
a second conductive pattern separated from the first conductive pattern by a gap,
wherein the first conductive pattern and the second conductive pattern configured to be connected by a laser irradiation during a repair process.

2. The fuse according to claim 1, wherein the first conductive pattern and the second conductive pattern are formed in the same plane.

3. The fuse according to claim 1, further comprising:
an insulating layer which is formed over the first conductive pattern and the second conductive pattern and the gap separating the first conductive pattern and the second conductive pattern,
wherein an overhang is provided between the first and second conductive patterns and above the gap.

4. The fuse according to claim 3, wherein the gap is smaller than ⅓ to 1/2.5 of a height of the first conductive pattern.

5. The fuse according to claim 1, wherein an end portion of the first conductive pattern has a convex form, and an end portion of the second conductive pattern has a concave form to receive the convex form of the first conductive pattern.

6. The fuse according to claim 1, wherein the end portion of the first conductive pattern and the end portion of the second conductive pattern are symmetrically formed with respect to each other.

7. The fuse according to claim 1, wherein the first conductive pattern and the second conductive pattern each includes tungsten, aluminium, titanium, copper, titanium nitride, iridium oxide, tungsten silicide, or titanium silicide, or a combination thereof.

8. A method of manufacturing a fuse of a semiconductor device, the method comprising:
forming a plurality of fuses on a substrate; and
forming an insulating layer over the fuses, each fuse having a first conductive pattern and a second conductive pattern that are separated by a gap.

9. The method according to claim 8, wherein an overhang is defined over the gap between the first and second conductive patterns by the insulating layer.

10. The method according to claim 9, wherein the gap no more than ⅓ to 1/2.5 of a height of the first conductive pattern.
